(19) United States
(12) Patent Application Publication
(10) Pub. No.: US 2009/0151774 A1
(43) Pub. Date: Jun. 18, 2009

(54) Method for Producing Weather-Resistant Laminates for Encapsulating Solar Cell Systems

(75) Inventors: Nicole Depine, Graz (AT); Joachim Danilko, Lebring (AT)

Correspondence Address: YOUNG & THOMPSON, 209 Madison Street, Suite 500, ALEXANDRIA, VA, 22314, US

(73) Assignee: ISOVOLTA AG, WIENER NEUDORF (AT)

(21) Appl. No.: 11/989,195

(22) PCT Filed: Jul. 10, 2006
(86) PCT No.: PCT/AT2006/000295

§ 371 Date: Mar. 25, 2008

(30) Foreign Application Priority Data
Jul. 21, 2005 (AT) A1230/2005

(51) Int. Cl. H01L 31/048; B32B 27/00; B32B 27/40; B32B 27/36; B05D 5/12; B32B 37/00

(52) U.S. Cl. 136/251; 428/421; 428/423.1; 428/446; 428/480; 428/335; 427/74; 156/60

(57) ABSTRACT

A process produces weather-resistant laminates (1, 1′) for the encapsulation of solar cell systems (7). The process includes at least one weather-resistant plastic layer (2, 2′) being applied on a carrier material (4, 4′). The coating process shows the advantage that the relatively expensive starting products, which usually are used in the form of films, can be reduced in their thickness and in amounts thereof used. Owing to the controllable adjustment of the layer thickness of the weather-resistant layer (2, 2′), a considerable number of applications of the laminates that are produced, in particular in connection with the finished photovoltaic modules, are provided. These applications range from small energy units for emergency telephones or campers to large-area roof and facade systems and also large units and solar power plants.

### BACKGROUND OF THE INVENTION

1. Field of the Invention

The invention relates to a process for the production of weather-resistant laminates for the encapsulation of solar cell systems as well as their use for the production of photovoltaic modules.

2. Description of the Related Art

Photovoltaic modules are used for the production of electric power from sunlight and consist of a laminate, which contains a solar cell system, such as, e.g., silicon solar cells, as a core layer. This core layer is sheathed with encapsulation materials to ensure protection against mechanical and weather-induced effects. These materials can consist of one or more layers that are made of glass and/or plastic films and/or plastic laminates.

Processes for the production of weather-resistant film laminates for the encapsulation of photovoltaic cells are known from WO-A-94/29106, WO-A-01/67523 as well as WO-A-00/02257. In these modules, the solar cell system is protected not only against mechanical damage, but also against water vapor and in particular also against effects of the weather. Therefore, in the encapsulation material, primarily weather-resistant plastics, such as films that are made of fluoropolymers, are used.

These fluoropolymer films are produced in a separate process, for example by extrusion or film-casting. These processes, however, are energy-intensive and costly.

Moreover, the production of fluoropolymer films based on their limited tensile strength is possible only in certain minimum thicknesses.

### BRIEF SUMMARY OF THE INVENTION

Here, the invention is intended to correct this.

It is therefore the object of this invention to indicate a process of the above-mentioned type with which weather-resistant laminates can also be produced in small layer thicknesses that are economical with respect to energy and costs. In addition, despite the small layer thicknesses, a satisfactory weather resistance for outside use is to be achieved.

According to the invention, a process for the production of weather-resistant laminates for the encapsulation of solar cell systems is proposed, which is characterized in that at least one weather-resistant plastic layer is applied on a carrier material.

Advantageous embodiments of the process according to the invention are disclosed in the subclaims.

Furthermore, the invention relates to the use of at least two laminates that are produced according to the process of the invention for the production of a photovoltaic module, whereby the solar cell system is applied to one of the laminates. This laminating process can be run continuously or in batches.

### BRIEF DESCRIPTION OF THE DRAWING FIGURES

The invention is explained in more detail below based on exemplary representations—see FIGS. 1 to 4—as well as possible means of implementation.

FIG. 1 shows the exemplary design of a photovoltaic module 18 with the encapsulation material 1, 1′ that is produced by the process according to the invention. The encapsulation material 1, 1′ includes a weather-resistant layer 2, 2′ and a carrier material 4, 4′, on which an adhesion layer 5, 5′ adjoins the sealing layer 6, 6′ for the solar cell system 7 as an adhesive.

FIG. 2 shows the exemplary design of an encapsulation material 1, as depicted in FIG. 1, in which an oxide layer 8, deposited from the vapor phase, is provided to further improve the weathering properties.

FIG. 3 shows a possible device for applying the weather-resistant layer 2, 2′ that is made of a polymer solution.

FIG. 4 shows a possible laminating device for the production of a pre-composite 17 for a photovoltaic module.

### DETAILED DESCRIPTION OF THE PREFERRED EMBODIMENTS

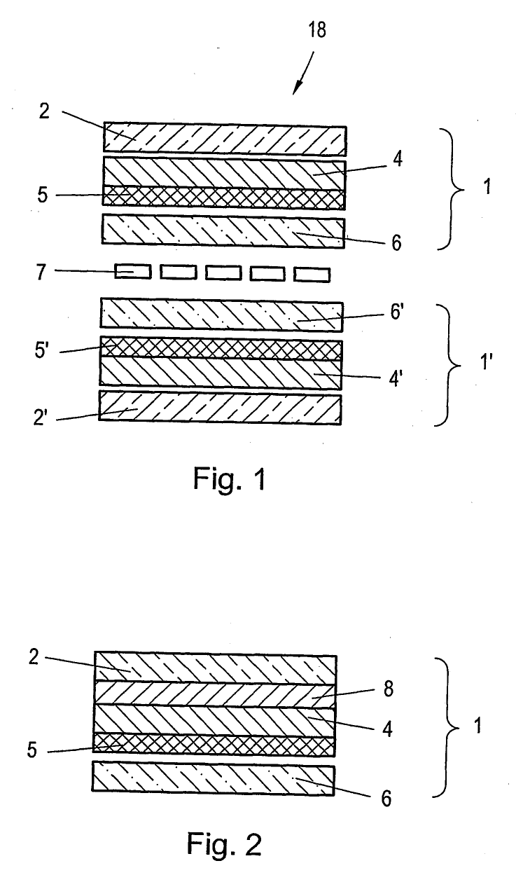

For the production of an encapsulating material 1 according to FIG. 1 or FIG. 2, a weather-resistant layer 2, 2′ and an adhesion layer 5, 5′ are applied in a first process step to the carrier material 4, 4′.

The examples a) to d) reproduce possible variants for the selection of the components in the respective layers:

### EXAMPLE a)

Weather-resistant layer 2, 2′: selectively soluble fluoropolymers or fluoro-copolymers, acrylates, polyurethanes, silicones and mixtures thereof for the direct coating on the carrier materials 4, 4′:

Adhesive layer 3, 3′: polyurethane, polyester;

Carrier material 4, 4′: polyethylene terephthalate (PET), polyethylene naphthenate (PEN), ethylene tetrafluoroethylene copolymer (ETFE), as well as co-extrudates therefrom in the form of films or laminates, aluminum foils in various thicknesses;

Adhesion layer 5, 5′: polyurethane, polyacrylate or surface-treated fluoropolymer layer;

Sealing layer 6, 6′: ethylene vinyl acetate (EVA), polyvinyl butyral (PVB), ionomers, polymethyl methacrylate (PMMA), polyurethane, polyester or hot melt.

### EXAMPLE b)

Weather-resistant layer 2, 2′: selectively soluble fluoropolymers or fluoro-copolymers, acrylates, polyurethanes, silicones, as well as mixtures therefrom for the direct coating on pretreated carrier materials 4, 4′;

Carrier material 4, 4′: polyethylene terephthalate (PET), polyethylene naphthenate (PEN), ethylene tetrafluoroethylene copolymer (ETFE) as well as co-extrudates therefrom in the form of films or laminates, aluminum foils in various thicknesses;

Adhesion layer 5, 5′: polyurethane, polyacrylate or surface-treated fluoropolymer layer;

Sealing layer 6, 6′: ethylene vinyl acetate (EVA), polyvinyl butyral (PVB), ionomers, polymethyl methacrylate (PMMA), polyurethane, polyester or hot melt.

### EXAMPLE c)

Weather-resistant layer 2, 2′: selectively soluble/dispersible fluoropolymers or fluoro-copolymers, with a melting point below the laminating temperature for the direct coating on the carrier materials 4, 4′;

Adhesive layer: polyurethane, polyester;

Carrier material 4, 4′: polyethylene terephthalate (PET), polyethylene naphthenate (PEN), ethylene tetrafluoroethylene copolymer (ETFE) as well as co-extrudates therefrom in the form of films or laminates, aluminum foils in various thicknesses;

Adhesion layer 5, 5′: polyurethane, polyacrylate or surface-treated fluoropolymer layer;

Sealing layer 6, 6′: ethylene vinyl acetate (EVA), polyvinyl butyral (PVB), ionomers, polymethyl methacrylate (PMMA), polyurethane, polyester or hot melt.

### EXAMPLE d)

Weather-resistant layer 2, 2′: selectively soluble/dispersible fluoropolymers or fluoro-copolymers, with a melting point below the laminating temperature for the direct treatment on a pretreated carrier material 4a, 4a′;

Carrier material 4a, 4a′: polyethylene terephthalate (PET), polyethylene naphthenate (PEN), ethylene tetrafluoroethylene copolymer (ETFE) as well as co-extrudates therefrom in the form of films or laminates, aluminum foils in various thicknesses;

Adhesion layer 5, 5′: polyurethane, polyacrylate or surface-treated fluoropolymer layer;

Sealing layer 6, 6′: ethylene vinyl acetate (EVA), polyvinyl butyral (PVB), ionomers, polymethyl methacrylate (PMMA), polyurethane, polyester or hot melt.

A carrier material 4, 4′, which is selected according to Examples a) to d), is provided with a weather-resistant layer 2, 2′. The polymers for the production of the weather-resistant layer 2, 2′ are selected according to Examples a) to d). If, in this case, as cited in Examples c) and d), a fluoropolymer or fluoro-copolymer is used primarily as a weather-resistant layer, a film that is uniform in its chemical constitution is thus produced. If, however, chemically different polymers, as cited in Examples a) and b), are used, it is also possible to use polymer mixtures for the weather-resistant layer 2, 2′. In this case, the polymer raw materials that are used are varied in their ratios such that the physical and/or chemical properties of the finished weather-resistant layer 2, 2′ can be modified or optimized in any way desired.

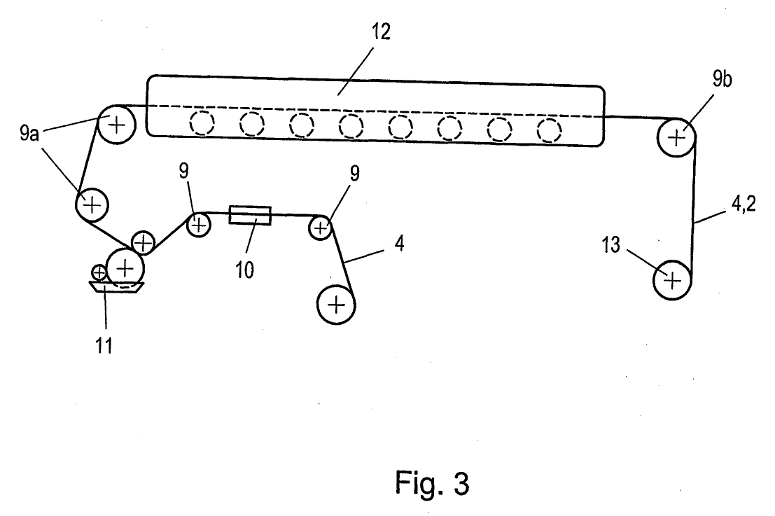

To increase the weather resistance and also to increase the bonding of adjacent composite layers, the carrier material can be pretreated before coating with the weather-resistant layer 2, 2′. The pretreatment can take place, on the one hand, by application of an additional adhesive, as well as, on the other hand, by application of an inorganic oxide layer, preferably a silicon oxide layer, that is deposited from the vapor phase. Furthermore, it is possible, as shown in FIG. 3, to perform the pretreatment of the carrier material 4, 4′ by means of physical media in the system 10. Subsequently, the carrier material 4, 4′ is fed for coating a coating head 11, in which the weather-resistant plastics are present in dissolved or dispersed form. As solvents, halogen-free organic solvents are used for environmental as well as disposal reasons. Furthermore, the solution or dispersion can have dyes.

Furthermore, during coating, it has proven advantageous to use dispersions, since during production of a dispersion, the amounts of solvent can be significantly reduced. For example, a flouoropolymer is dissolved at 40-100° C. and at a stirring speed of at least 2800 rpm by means of an intensive stirrer or dissolver under reflux in 2-butanone. Various fillers or dyes, such as titanium dioxide or carbon black, can be added to the solution up to a proportion of 35% relative to the fluoropolymer that is used, so that a dispersion is formed. The latter is applied via the coating machine 11 to the carrier material 4, 4′, for example a pretreated PET film. The layer thickness of the weather-resistant layer 2, 2′, which lies in a range of 5 to 50 μm, for example, is controlled by adjusting the roll gap in the coating machine 11. The thus coated material 4, 4′ is then fed via the deflecting rollers 9a to a dryer 12, in which the solvent that is used is evaporated at temperatures of between 80° C. and 180° C. Exhaust air and temperature adjustments in the dryer are selected such that a bubble-free, dry coating is produced. The residual solvent content of 0.3-0.6% is used as a criterion for the specific temperature adjustment.

Furthermore, the carrier material 4, 4′ that is provided with the layer 2, 2′ is fed via a deflecting roller 9b to the storage roll 13 and wound up on the latter.

In an additional process step, the carrier material 4, 4′, provided on one side with the weather-resistant layer 2, 2′, can now be coated on the still uncoated surface side with the adhesion layer 5, 5′. This is carried out with use of the system that is shown in FIG. 3, whereby polyurethanes as well as fluoropolymers are used as starting products. After the coating, the fluoropolymers can be chemically or physically surface-treated.

For the production of the encapsulating material 1, 1′ as shown in FIG. 1, the roll is now cut to length in batches and connected in conventional laminating processes to the sealing layer 6, which can be selected according to Examples a) to d).

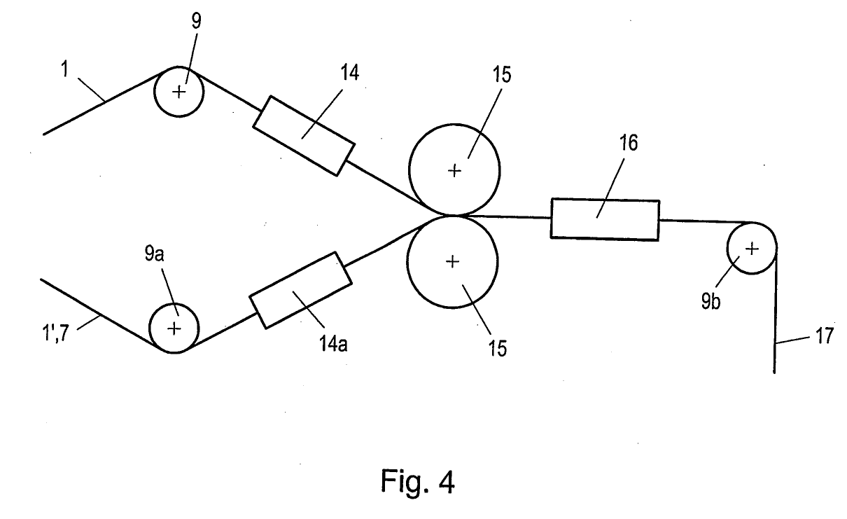

A composite of the layers 2, 4, 5 and 6 or 2′, 4′, 5′ and 6′ is added by the laminating process, but the further hardening of the plastics that are used in the composite is carried out in the finishing of the photovoltaic module 17, which, as shown in FIG. 4, can be carried out, for example, by a so-called roll-to-roll process.

In this case, for example, the solar cell system 7, consisting of flexible solar cell types, is applied on the encapsulating material 1′. Another encapsulating material layer 1 is removed from the opposite storage roll 9 and fed to the solar cell system 7. In this case, the material webs that are drawn off from the storage roll 9 or 9a are fed in each case to a heating station 14 or 14a, in which the encapsulating materials 1, 1′ are heated at least to the softening temperature of the sealing layer 6, 6′. As a result, the design of a composite between the layers 1, 1′, on the one hand, and the solar cell system 7, on the other hand, is ensured in the roll gap of the calender station 15. To achieve the hardening of this composite and the complete cross-Linking of the polymers used in the encapsulating materials, the pre-composite is fed to a heating station 16. The composite 17 for a photovoltaic module can be stored on the storage roll 9b and can be removed from the latter in a suitable manner.

Relatively thin material systems, in particular as regards the weather-resistant layer 2, 2′, can be achieved by the coating process according to the invention in a photovoltaic module 18, whose layer design is shown in FIG. 1.

This has the advantage that with removal of the photovoltaic modules, the proportion of fluorine-containing polymers can be reduced in comparison to commercially available module superstructures.

Furthermore, it is possible within the scope of the process according to the invention to produce not only a chemically uniform polymer film for the coating 2, 2′, but also to prepare a mixture that consists of various polymer raw materials in varying ratios. As known from the prior art, the use of polymer films was essentially limited to a polymer type. According to the invention, however, a mixture can be prepared for the weather-resistant layer 2, 2′, in which the physical and/or chemical properties of the finished coating 2, 2′ can be modified and optimized in any way desired by selection and amounts of the polymer raw materials that are used.

Independently thereof, production is economical in process, since the thickness of the weather-resistant layer 2, 2′ is reduced, and thus the amounts of relatively costly fluoropolymers can be reduced. The process can be performed in situ, which essentially facilitates the execution of the process. By selection of the polymers and solvents that are used, temperature ranges, which are advantageously between 80 and 180° C., are adjusted so that an energy-saving implementation of the process is also made possible.

In addition, depending on the purpose, the thickness of the weather-resistant layer 2, 2′ can be adjusted. By adjusting this layer thickness, a large number of applications of the photovoltaic module are possible with use of the encapsulating materials that are produced according to the invention, and said applications range from small energy units for emergency telephones or campers to large-area roof and facade systems and also large units and solar power plants.

1-23. (canceled)

24. A process for the production of weather-resistant laminates for the encapsulation of solar cell systems, comprising:
applying at least one weather-resistant plastic layer on a carrier material.

25. The process according to claim 24, wherein the weather-resistant plastic layer is formed from at least one material selected from the group consisting of selectively soluble fluoropolymers or fluoro-copolymers, acrylates, polyurethanes, and silicones.

26. The process according to claim 24, wherein the weather-resistant plastics are a solution and/or a dispersion when applied on the carrier material.

27. The process according to claim 26, wherein the solution or dispersion contains at least one dye.

28. The process according to claim 24, wherein a process temperature is between 80 and 180° C.

29. The process according to claim 24, wherein the weather-resistant plastics have a layer thickness of 5 to 50 μm.

30. The process according to claim 24, wherein the weather-resistant layer is transparent in the visible light wave range and in the near UV-wavelength range.

31. The process according claim 24, wherein the carrier material is selected from the group consisting of polyethylene terephthalate (PET), polyethylene naphthenate (PEN), ethylene tetrafluoroethylene copolymer (ETFE), and co-extrudates therefrom.

32. The process according to claim 24, wherein the carrier material is an aluminum foil.

33. The process according to claim 24, wherein the carrier material is physically and/or chemically pretreated before the applying.

34. The process according to claim 24, further comprising:
depositing an inorganic oxide layer from the vapor phase on the carrier material.

35. The process according to. claim 24, further comprising:
applying an adhesive to the carrier material.

36. The process according to claim 35, wherein a polyurethane or polyester adhesive is used the adhesive.

37. The process according to claim 24, further comprising:
applying an adhesion layer on an uncoated side of the carrier material.

38. The process according to claim 37, wherein the adhesion layer is prepared by a primer system, a surface-treated fluoropolymer/fluoro-copolymer layer, or a polyurethane or polyacrylate layer.

39. The process according to claim 37, further comprising:
applying a sealing layer, adjoining the adhesion layer.

40. The process according to claim 39, wherein the sealing layer is formed from at least one material selected from the group consisting of ethylene vinyl acetate (EVA), polyvinyl butyral (PVB), ionomers, polymethyl methacrylate (PMMA), polyurethane, polyester and hot melt polymers.

41. A process for the production of a photovoltaic module, comprising:
applying a solar cell system to at least the laminate according to the process of claim 24.

42. The process according to claim 41, wherein the production of the photovoltaic module is carried out by a batch process, or the production of the photovoltaic module is carried out by a continuous laminating process, in which a pre-composite for the photovoltaic module is produced.

43. The process according to claim 42, wherein for the production of the pre-composite, a more flexible solar cell is used.

44. The process e according to claim 41, wherein the solar cell system comprises silicon solar cells.

45. A repair process, comprising:
applying the dispersion of claim 26 to a damaged back side of a photovoltaic module.

46. A fluoropolymer coated film, comprising:
a polymeric substrate film; and
a fluoropolymer coating on said polymeric substrate film.

47. A photovoltaic module, comprising:
the fluoropolymer coated film of claim 46 as backsheet.

48. A liquid fluoropolymer coating composition, comprising:
a fluoropolymer;
a solvent; and
a compatible adhesive polymer.
